(19) United States
(12) Patent Application Publication
(10) Pub. No.: US 2024/0355678 A1
(43) Pub. Date: Oct. 24, 2024

(54) METHODS OF DICING WAFERS HAVING ARRAYS OF SEMICONDUCTOR CHIPS THEREIN AND SEMICONDUCTOR CHIPS FORMED THEREBY

(71) Applicant: Samsung Electronics Co., Ltd., Suwon-si (KR)

(72) Inventors: Junho Yoon, Suwon-si (KR); Junyun Kweon, Suwon-si (KR); Haemin Park, Suwon-si (KR); Kwangyong Lee, Suwon-si (KR); Jesung Kim, Suwon-si (KR); Dayoung Cho, Suwon-si (KR)

(21) Appl. No.: 18/636,463

(22) Filed: Apr. 16, 2024

(30) Foreign Application Priority Data
Apr. 19, 2023 (KR) 10-2023-0051431
Jul. 17, 2023 (KR) 10-2023-0092476

(51) Int. Cl. H01L 21/78; H01L 23/00

(52) U.S. Cl. CPC H01L 21/78; H01L 24/08; H01L 24/80; H01L 2224/08145; H01L 2224/80895; H01L 2224/80896

(57) ABSTRACT

A semiconductor chip includes an active layer on a top surface of an underlying base substrate. The active layer has: bonding surface therein that delineates an interface between a bottom active layer and a top active layer extending on the bottom active layer, and a chamfered edge that extends entirely through the top active layer to fully expose a sidewall thereof but only partially through the bottom active layer, such that the chamfered edge has a vertical height greater than a thickness of the top active layer but less than a combined thickness of the top and bottom active layers. A protective layer is also provided, which covers at least a portion of a top surface of the active layer. A vertical level of a bottom of the chamfered edge may be higher than a vertical level of the top surface of the base substrate.

### REFERENCE TO PRIORITY APPLICATIONS

This application claims priority under 35 U.S.C. § 119 to Korean Patent Application Nos. 10-2023-0051431, filed Apr. 19, 2023, and 10-2023-0092476, filed Jul. 17, 2023, the disclosures of which are hereby incorporated herein by reference.

### BACKGROUND

The inventive concept relates to semiconductor fabrication methods and devices formed thereby and, more particularly, to methods of forming semiconductor chips and semiconductor chips formed thereby.

In a process of manufacturing a semiconductor chip, a surface of a semiconductor wafer having the form of an approximately circular plate is divided into a plurality of regions using partition due lines, which are arranged in the form of a two-dimensional grid pattern. Devices, such as integrated circuits (IC) and large scale integrations (LSI), are typically formed in the plurality of regions. As will be understood by those skilled in the art, by cutting the semiconductor wafer along the partition due lines, the regions in which the devices are formed are divided to thereby yield individual device chips. During a process of dividing the semiconductor wafer, external forces may be applied to an active layer within the regions, and thereby cause a shortening of the lifespan of the resulting device chips.

### SUMMARY

The inventive concept provides a semiconductor chip that is fabricated such that generation of cracks in a bonding surface is inhibited during a process of dividing a semiconductor wafer having an array of semiconductor chips therein, and methods of dicing a wafer having an array of semiconductor chips therein.

According to an aspect of the inventive concept, there is provided a semiconductor chip including a base substrate, an active layer formed on a top surface of the base substrate, a protective layer covering at least a portion of the top surface of the active layer and being apart from the base substrate in a vertical direction with the active layer therebetween. A first chamfer extends inside from the top surface of the active layer and forms along an edge of the top surface of the active layer. The active layer includes a top active layer and a bottom active layer, which are distinguished from each other with reference to a bonding surface in the active layer. A vertical level of a bottom of the first chamfer is lower than a vertical level of the bonding surface in the active layer.

According to another aspect of the inventive concept, there is provided a method of dicing a wafer, the method including forming a trench along a partition due line (PDL) of a wafer by concentrating a first laser beam on a surface of the wafer and removing a portion of a protective layer and a portion of an active layer. The wafer includes a base substrate, and the active layer is formed on a surface of the base substrate and has a bonding surface therein. A protective layer covers the active layer. The method further includes positioning, in the base substrate, a concentration point of a second laser beam having a wavelength transmitted through the wafer, and forming a modifier in the base substrate along the PDL. In addition, during forming of the trench, a portion on the PDL is removed from the bonding surface of the active layer.

According to another aspect of the inventive concept, there is provided a method of dicing a wafer, which includes forming a trench along a PDL of a wafer by concentrating a first laser beam on a surface of the wafer and removing a portion of a protective layer and a portion of an active layer. The wafer includes a base substrate, and the active layer is formed on a surface of the base substrate and has a bonding surface therein. The protective layer covers the active layer. The method further includes: positioning, in the base substrate, a concentration point of a second laser beam having a wavelength transmitted through the wafer, and forming a modifier in the base substrate along the PDL, grinding a bottom surface of the wafer, and cutting the wafer along the PDL by applying an external force to the wafer. A portion on the PDL is removed from the bonding surface of the active layer during the forming of the trench.

According to another aspect of the inventive concept, there is provided a method of dicing a wafer, which includes: (i) forming a modifier in a base substrate along a PDL of a wafer by positioning, in the base substrate, a concentration point of a second laser beam having a wavelength transmitted through the wafer, which includes the base substrate, an active layer formed on a surface of the base substrate (and having a bonding surface therein), and a protective layer covering the active layer, (ii) aligning the modifier a concentration point of the first laser beam after the forming of the modifier, and then, after the aligning, (iii) forming the trench along the partition due line of the wafer by concentrating the first laser beam onto a top surface of the wafer and removing a portion of the protective layer and a portion of the active layer, (iv) grinding a bottom surface of the wafer, and (v) cutting the wafer along the partition due line by applying an external force to the wafer.

### BRIEF DESCRIPTION OF THE DRAWINGS

Embodiments will be more clearly understood from the following detailed description taken in conjunction with the accompanying drawings in which:

FIG. 1 is a perspective view schematically illustrating a wafer according to some embodiments;

FIG. 2 is a perspective view schematically illustrating a portion of the wafer shown in FIG. 1;

FIG. 3 is a cross-sectional view schematically illustrating the wafer of FIG. 2, taken along a line B-B′ shown in FIG. 2;

FIG. 4 is a perspective view schematically illustrating a semiconductor chip according to some embodiments;

FIG. 5 is a cross-sectional view schematically illustrating the semiconductor chip of FIG. 4, taken along a line A-A′ shown in FIG. 4;

FIG. 6 is a cross-sectional view schematically illustrating a semiconductor chip according to some embodiments, taken along the line A-A′ shown in FIG. 4;

FIG. 7 is a cross-sectional view schematically illustrating a semiconductor chip according to some embodiments, taken along the line A-A′ shown in FIG. 4;

FIG. 8 is a cross-sectional view schematically illustrating a semiconductor chip according to some embodiments, taken along the line A-A′ shown in FIG. 4;

FIG. 9 is a cross-sectional view schematically illustrating a semiconductor chip according to some embodiments, taken along the line A-A′ shown in FIG. 4;

FIG. 10 is a flowchart schematically illustrating a method of dicing a wafer, according to some embodiments;

FIGS. 11A, 12A, 13A, 14A, and 15A are perspective views illustrating a method of dicing a wafer, according to some embodiments, according to a process order;

FIGS. 11B, 12B, 13B, 14B, 15B, and 12C are cross-sectional views illustrating a method of dicing a wafer, according to some embodiments, according to a process order;

FIG. 16 is a flowchart schematically illustrating a method of dicing a wafer, according to some embodiments;

FIGS. 17A, 18A, 19A, 20A, and 21A are perspective views illustrating a method of dicing a wafer, according to some embodiments, according to a process order; and

FIGS. 17B, 18B, 19B, 20B, and 21B are cross-sectional views illustrating a method of dicing a wafer, according to some embodiments, according to a process order.

### DETAILED DESCRIPTION OF THE EMBODIMENTS

As the inventive concept allows for various changes and numerous embodiments, some embodiments will be illustrated in the drawings and described in detail in the written descriptions. However, this is not intended to limit the inventive concept to particular modes of practice.

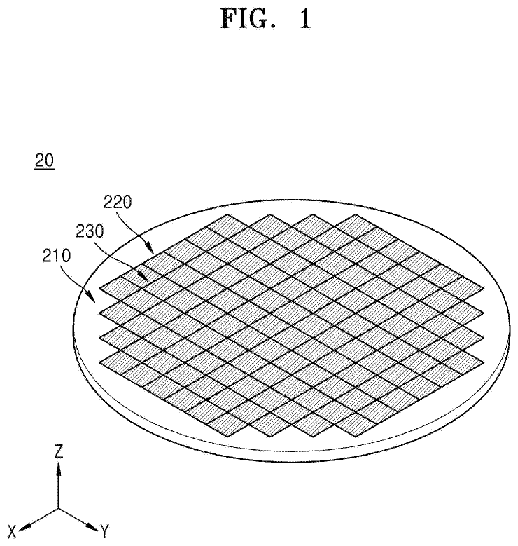

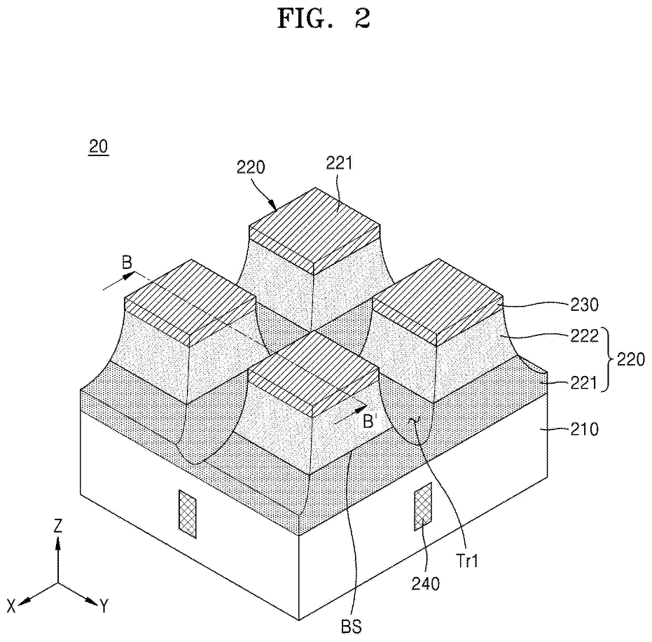

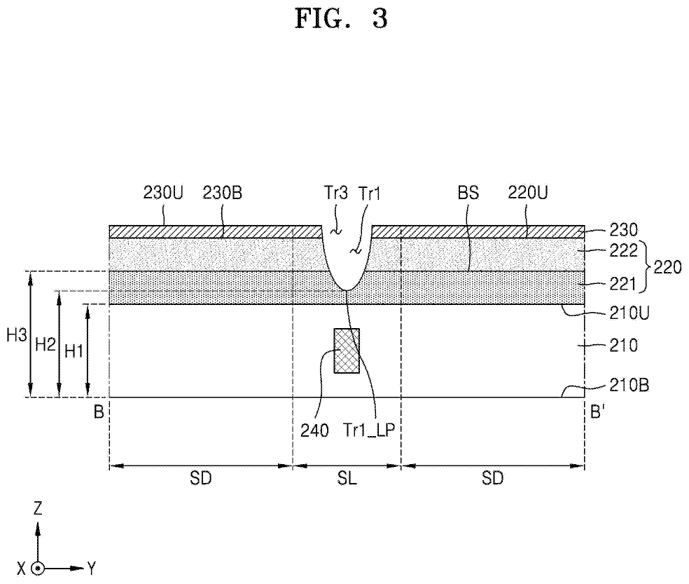

FIG. 1 is a perspective view schematically illustrating a wafer 20 according to some embodiments. FIG. 2 is a perspective view schematically illustrating a portion of the wafer 20 shown in FIG. 1. FIG. 3 is a cross-sectional view schematically illustrating the wafer 20 shown in FIG. 2, taken along a line B-B′. Referring to FIGS. 1 to 3, the wafer 20 may include a base substrate 210, an active layer 220, a modifier 240, and a protective layer 230.

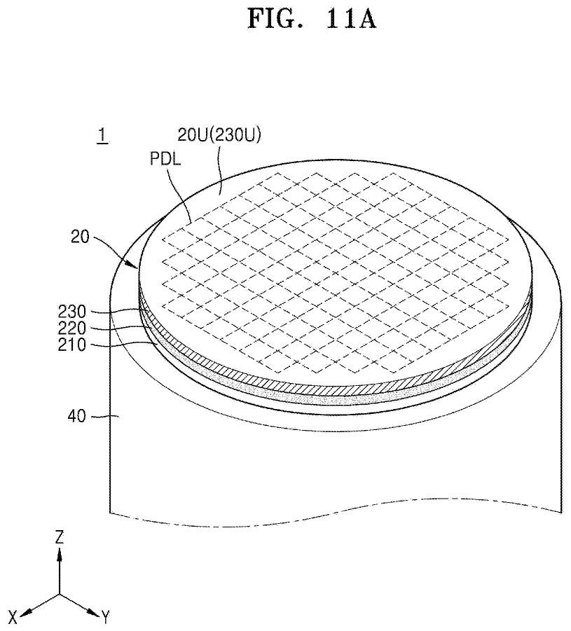

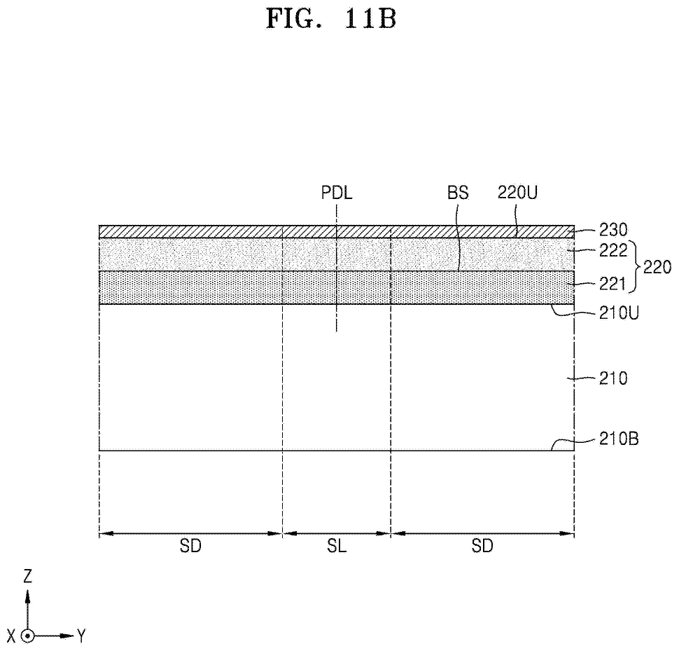

The wafer 20 may include a plurality of device-forming regions SD, in each of which a plurality of integrated devices are formed, and a scribe lane region SL defining the plurality of device-forming regions SD. A partition due line (a partition due line PDL shown in FIG. 11A) may be in the scribe lane region SL. In addition, a first trench Tr1 and the modifier 240 may be in the scribe lane region SL. Hereinafter, unless particularly defined otherwise, a direction parallel to a top surface 210U of the base substrate 210 is defined as a first horizontal direction (an X direction), a direction perpendicular to the top surface 210U of the base substrate 210 is defined as a vertical direction (a Z direction), and a direction perpendicular to the first horizontal direction (the X direction) and the vertical direction (the Z direction) is defined as a second horizontal direction (the Y direction).

The base substrate 210 of the wafer 20 may include silicon (Si). However, the material of the base substrate 210 is not limited to Si. For example, the base substrate 210 may include another semiconductor element, e.g., germanium (Ge), or a compound semiconductor, e.g., SiC, GaAs, InAs, and InP. In addition, the base substrate 210 may have a silicon-on-insulator (SOI) structure. For example, the base substrate 210 may include a buried oxide (BOX) layer. The base substrate 210 of the wafer 20 may be referred to as an inactive layer.

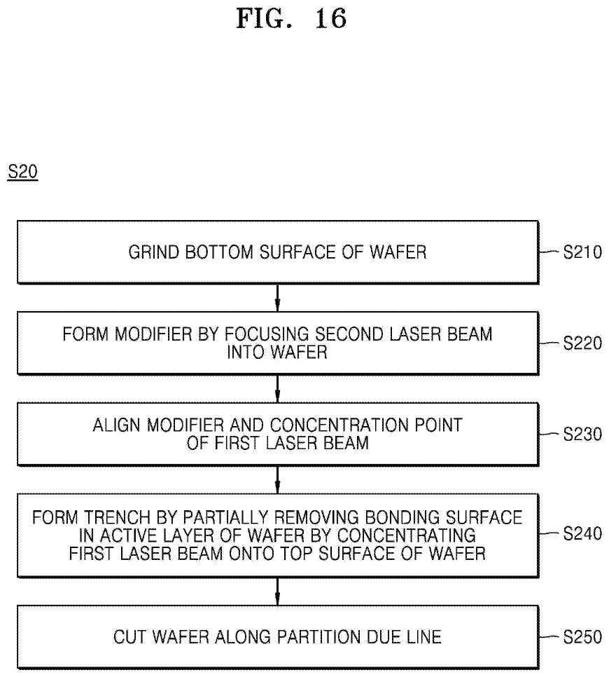

The modifier 240 of the wafer 20 may be included in the base substrate 210. The modifier 240 may be formed along the partition due line in the scribe lane region SL. For example, the modifier 240 may be spaced apart from the first trench Tr1 in the vertical direction (the Z direction). The modifier 240 may be formed by concentrating a second laser beam L2 (see FIG. 16) into the base substrate 210, and may be easily damaged by external forces, such as thermal stresses or cracks. Accordingly, the wafer 20 may be split into a plurality of wafer chips along the modifier 240.

As shown, the active layer 220 of the wafer 20 may be on the top surface 210U of the base substrate 210. In some embodiments, the active layer 220 may include a plurality of integrated devices. The plurality of integrated devices may include memory devices or logic devices. In some embodiments, integrated circuits such as integrated circuits (IC) and large scale integration (LSI) may be formed on the active layer 220. For example, the memory devices may include devices such as dynamic random access memory (DRAM), static random access memory (SRAM), flash memory, electrically erasable and programmable read-only memory (EEPROM), phase-change random access memory (PRAM), magnetic random access memory (MRAM), or resistive random access memory (RRAM). In addition, the logic devices may include AND, NAND, OR, NOR, exclusive OR (NOR), exclusive NOR (XNOR), inverter (INV), adder (ADD), buffer, delay (DLY), filter (FIL), multiplexer (MXT/MXIT), OR/AND/INVERTER (OAI), AND/OR (AO), AND/OR/INVERTER (AOI), D flip-flop, reset flip-flop, master-slave flip-flop, latch, counter, or buffer. The logic devices may also include a central processing unit (CPU), a micro-processor unit (MPU), a graphic processing unit (GPU), an application processor (AP), or the like.

In some embodiments, the active layer 220 may include a structure in which a top active layer 222 and a bottom active layer 221 are bonded to each other. A surface in which the top active layer 222 and the bottom active layer 221 are in contact with each other may include a bonding surface BS. In some embodiments, the active layer 220 may include a cell-on-peri (CoP) type of integrated device. That is, the top active layer 222 may include a cell region, and the bottom active layer 221 may include a peripheral region. In some embodiments, the top active layer 222 and the bottom active layer 221 may be bonded to each other using Hybrid bonding. More particularly, a top conductive pad and a top insulating layer may be on the top active layer 222, and a bottom conductive pad and a bottom insulating layer may be on the bottom active layer 221. The top conductive pad and the bottom conductive pad facing each other may expand due to heat and may be in contact with each other, and diffusion bonding may be performed such that the top conductive pad and the bottom conductive pad become integral with each other through diffusion of metal atoms included in the top conductive pad and the bottom conductive pad. During a process of forming the top conductive pad and the bottom conductive pad, the top insulating layer and the bottom insulating layer facing each other may expand due to heat and may be in contact with each other, and the top conductive pad and the bottom conductive pad may be integrally formed through diffusion bonding through diffusion of the atoms included in the top conductive pad and the bottom conductive pad. However, methods of bonding the top active layer 222 and the bottom active layer 221 are not limited thereto.

In some embodiments, the bonding surface BS may have a bonding structure using an anisotropic conductive film (ACF), or a bonding structure using a contact member such as bumps or solder balls. In the bonding structure using an ACF, the ACF, in which electricity moves only in one direction, may indicate a conductive film manufactured in a film state by mixing fine conductive particles with an adhesive resin.

The active layer 220 may include the first trench Tr1. The first trench Tr1 may be formed along the partition due line PDL (see FIG. 11A) of the wafer 20. The wafer 20 may be diced with reference to the first trench Tr1, and by doing so, a plurality of semiconductor chips may be manufactured. As shown by FIG. 3, the first trench Tr1 may extend inside from a top surface 220U of the active layer 220. The first trench Tr1 may be formed by partially removing a portion of the active layer 220 on the partition due line PDL (see FIG. 11A). A lowermost portion Tr1_LP of the first trench TR1 is defined as a portion most adjacent to the base substrate 210 in a surface of the active layer 220 defining the first trench Tr1. The lowermost portion Tr1_LP of the first trench TR1 may be lower than the bonding surface BS of the active layer 220 in the vertical direction (the Z direction). That is, in the region in which the first trench Tr1 is formed, a portion of the bonding surface BS of the active layer 220 may be removed.

A vertical level H2 of the lowermost portion Tr1_LP of the first trench TR1 may be lower than a vertical level H3 of the bonding surface BS of the active layer 220. In some embodiments, the vertical level H2 of the lowermost portion Tr1_LP of the first trench TR1 may be lower than the vertical level H3 of the bonding surface BS and higher than a vertical level H1 of the top surface 210U of the base substrate 210. For example, the lowermost portion Tr1_LP of the first trench TR1 may be in the bottom active layer 221. Hereinafter, the term “vertical level” used herein indicates a distance from a bottom surface 210B of the base substrate 210.

During a process where the wafer 20 is separated, when cracks extend from the modifier 240 to the first trench Tr1, the cracks may not extend to the bonding surface BS of the active layer 220. By forming the first trench Tr1, in the process where the wafer 20 is separated, damage to the active layer 220 with reference to the bonding surface BS may be inhibited.

The protective layer 230 of the wafer 20 may be on the active layer 220. The protective layer 230 may cover at least a portion of the top surface 220U of the active layer 220. The protective layer 230 may be apart from the base substrate 210 with the active layer 220 therebetween. In some embodiments, the protective layer 230 may include a third trench Tr3 extending inside from a top surface 230U of the protective layer 230. The third trench Tr3 may be referred to as a through hole. The third trench Tr3 may completely penetrate from the top surface 230U of the protective layer 230 to a bottom surface 230B of the protective layer 230, and may be aligned with the first trench Tr1, as shown. In a process of forming the first trench Tr1, the protective layer 230 on the active layer 220 may be first removed, and then the active layer 220 may be removed. Accordingly, the first trench Tr1 of the active layer 220 and the third trench Tr3 of the protective layer 230 may be simultaneously formed and may be aligned with each other, such that the first trench Tr1 and the third trench Tr3 are the same trench.

In some embodiments, the protective layer 230 may include a high-molecular compound film. For example, the protective layer 230 may include photosensitive polyimide (PSPI) or polyimide (PI). For example, the protective layer 230 may include poly vinyl alcohol (PVA), polyethylene glycol (PEG), and polyethylene oxide (PEO). Advantageously, the protective layer 230 may inhibit arrival of impurities, which are generated in processes of forming the first trench Tr1 and the third trench Tr3, to the active layer 220.

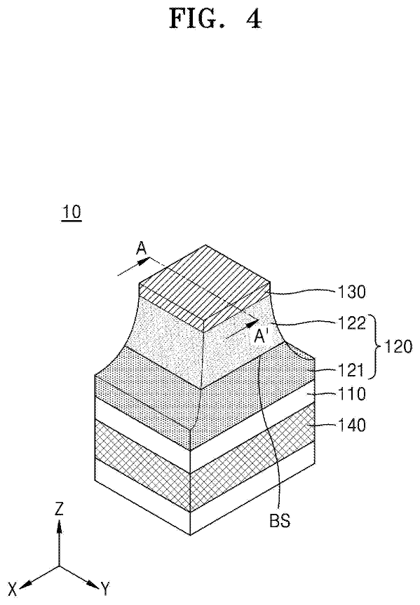

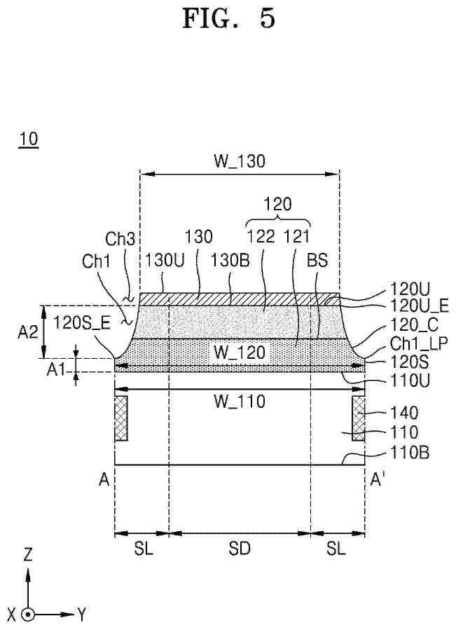

FIG. 4 is a perspective view schematically illustrating a semiconductor chip 10 according to some embodiments. FIG. 5 is a cross-sectional view schematically illustrating the semiconductor chip 10 shown in FIG. 4, taken along a line A-A′. Referring to FIGS. 4 and 5, the semiconductor chip 10 may include a base substrate 110, an active layer 120, a modifier 140, and a protective layer 130. The semiconductor chip 10 may be manufactured by dicing the wafer 20 (see FIG. 2) along the partition due lines. Hereinafter, same descriptions of the semiconductor chip 10 in FIG. 4 and the wafer 20 (see FIG. 1) will be omitted, and only differences therebetween will be described.

The semiconductor chip 10 may include a device-forming region SD including a plurality of integrated circuit devices and a scribe lane region SL surrounding the device-forming region SD. The device-forming region SD may include a center of the semiconductor chip 10, and the scribe lane region SL may include a side surface of the semiconductor chip 10. The base substrate 110 of the semiconductor chip 10 may include Si; however, the material of the base substrate 210 is not limited to Si. For example, the base substrate 210 may include another semiconductor element, e.g., germanium (Ge), or a compound semiconductor, e.g., SiC, GaAs, InAs, and InP.

The modifier 140 of the semiconductor chip 10 may be included in the base substrate 110. The modifier 140 may be formed along the partition due line in the scribe lane region SL. The modifier 140 may be formed along a side surface of the base substrate 110. For example, the modifier 140 may extend along the side surface of the base substrate 110 and cover a portion of the base substrate 110. For example, when a horizontal cross-section of the base substrate 110 has a square shape, the modifier 140 may have a square ring shape.

A side of the modifier 140 may be exposed to outside, and another side of the modifier 140 may be facing (and within) an interior of the base substrate 110. The modifier 140 may be spaced apart from the first chamfer Ch1 in the vertical direction (the Z direction). The modifier 140 may be easily damaged by external forces, such as thermal stresses and cracks. Accordingly, when dicing the wafer 20 (see FIG. 1), the base substrate 110 may be partitioned with reference to the modifier 140, and the modifier 140 may be exposed to the outside. The modifier 140 may be spaced apart from the top surface 110U of the base substrate 110. The modifier 140 may be formed by concentrating a second laser beam L2 (see FIG. 16) into the base substrate 110.

The active layer 120 of the semiconductor chip 10 may be on the top surface 110U of the base substrate 110. The active layer 120 may include a region of the base substrate 110, in which a plurality of integrated devices are formed. The plurality of integrated devices of the active layer 120 may include the plurality of integrated devices of the active layer 120 of the wafer 20 (see FIG. 1) described above. The active layer 120 of the semiconductor chip 10 may include a top active layer 122 and a bottom active layer 121 distinguished by the bonding surface BS. In some embodiments, the active layer 120 may include a CoP type of integrated device, and the top active layer 122 may include a cell region and the bottom active layer 121 may include a peripheral region. However, the top active layer 122 and the bottom active layer 121 are not limited thereto. In some embodiments, the top active layer 122 and the bottom active layer 121 may be bonded to each other through hybrid bonding. That is, a top conductive pad and a top insulating layer of the top active layer 122 may be respectively combined to a bottom conductive pad and a bottom insulating layer of the bottom active layer 121. However, methods of bonding the top active layer 122 and the bottom active layer 121 are not limited thereto.

The active layer 120 may include the first chamfer Ch1 extending inside from a top surface 120U of the active layer 120. The first chamber Ch1 may be formed along an edge 120U_E of the top surface 120U of the active layer 120. For example, when the top surface 120U of the active layer 120 has a square shape, the first chamfer Ch1 may be formed along four sides of the top surface 120U of the active layer 120. The first chamfer Ch1 may cover the top surface 120U of the active layer 120.

In some embodiments, as the first trench Tr1 of the wafer 20 shown in FIG. 2 is diced along the partition due line, the first trench Tr1 may operate as the first chamfer Ch1 of each of the plurality of semiconductor chips 10. In some embodiments, the active layer 120 may include a top side surface 120_C defining the first chamfer Ch1 and a bottom side surface 120S on which the first chamfer Ch1 is not formed. The top side surface 120_C of the active layer 120 defining the first chamfers Ch1 may extend from an edge 120U_E of the top surface 120U of the active layer 120 to an edge 120S_E of the bottom side surface 120S of the active layer 120. In some embodiments, the top side surface 120_C of the active layer 120 defining the first chamfer Ch1 may include a curved surface.

For example, a horizontal width W_120 of the active layer 120 may change to correspond to the first chamfer Ch1. Thus, in a region where a horizontal width of the first chamfer Ch1 is greater, the horizontal width W_120 of the active layer 120 may be smaller. For example, in some embodiments, the horizontal width W_120 of the active layer 120 on the top surface 120U of the active layer 120 is smaller (i.e., about 15 μm to about 30 μm) than a horizontal width W_110 of a bottom surface 110B of the base substrate 110.

A vertical level of a lowermost portion Ch1_LP of the first chamfer Ch1 may be lower than a vertical level of the bonding surface BS of the active layer 120. The first chamfer Ch1 may be formed to a lower position than the bonding surface BS of the active layer 120 in the vertical direction (the Z direction). For example, the bonding surface BS may be on the top side surface 120_C of the active layer 120. The bonding surface BS of the active layer 120 may be not on the bottom side surface 120S of the active layer 120. In the process of forming the first chamfer Ch1, the bonding surface BS within the partition due line may be removed. Accordingly, in a process of partitioning the wafer 20 (see FIG. 1), extension of the cracks from the modifier 140 to the bonding surface BS may be inhibited.

In some embodiments, the lowermost portion Ch1_LP of the first chamfer Ch1 may be in the bottom active layer 121. That is, the vertical level of the lowermost portion Ch1_LP of the first chamfer Ch1 may be lower than the vertical level of the bonding surface BS and higher than the vertical level of the top surface 110U of the base substrate 110. Moreover, in a region A2 in which the first chamfer Ch1 is formed, the horizontal width W_120 of the active layer 120 may increase toward the base substrate 110, and in a region A1 in which the first chamfer Ch1 is not formed, the horizontal width W_120 of the active layer 120 may be identical to the horizontal width W_110 of the base substrate 110. For example, the region A2 in which the first chamfer Ch1 is formed may include a region in which the top side surface 120_C of the active layer 120 is located, and the region A1 in which the first chamfer Ch1 is not formed may include a region in which the bottom side surface 120S of the active layer 120 is located.

The protective layer 130 of the semiconductor chip 10 may be on the active layer 120, and may cover at least a portion of the top surface 120U of the active layer 120. As shown, the protective layer 130 may be apart from the base substrate 110 with the active layer 120 extending therebetween. In some embodiments, the protective layer 130 may include a third chamfer Ch3 extending inside from a top surface 130U of the protective layer 130. The third chamfer Ch3 may completely penetrate from the top surface 130U of the protective layer 130 to a bottom surface 130B of the protective layer 130. The third chamfer Ch3 may be aligned to the first chamfer Ch1. The third chamfer Ch3 may be formed along an edge of the top surface 130U of the protective layer 130, and may be formed to surround the top surface 130U of the protective layer 130.

In some embodiments, as the first trench Tr1 of the wafer 20 shown in FIG. 2 is diced along the partition due line, the first trench Tr1 may be the first chamfer Ch1 of each of the plurality of semiconductor chips 10. In some embodiments, a horizontal width W_130 of the protective layer 130 may decrease away from the active layer 120. The horizontal width W_130 of the protective layer 130 may change to correspond to a shape of the third chamfer Ch3. The protective layer 130 may inhibit arrival of impurities, which are generated in the processes of forming the first trench Ch1 and the third trench Ch3 of the semiconductor chip 10, to the active layer 120.

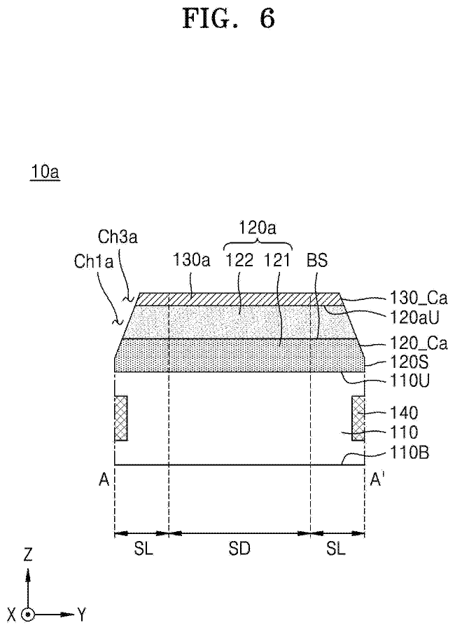

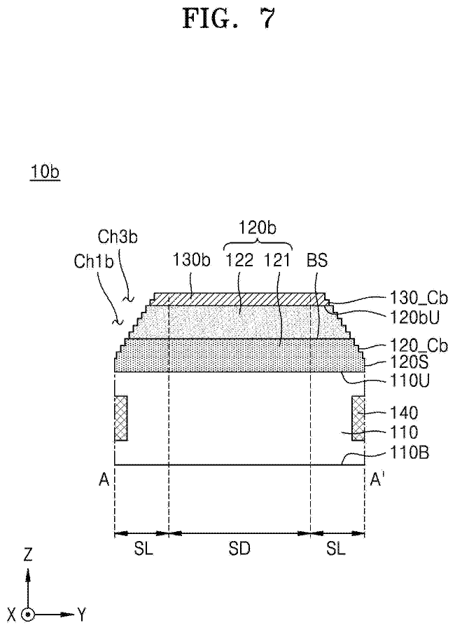

FIG. 6 is a cross-sectional view schematically illustrating a semiconductor chip 10a according to some embodiments, taken along a line A-A′ shown in FIG. 4; and FIG. 7 is a cross-sectional view schematically illustrating a semiconductor chip 10b according to some embodiments, taken along a line A-A′ shown in FIG. 4. Referring to FIGS. 6 and 7, the semiconductor chip 10a may include the base substrate 110, an active layer 120a, the modifier 140, and a protective layer 130a. And, the semiconductor chip 10b may include the base substrate 110, an active layer 120b, the modifier 140, and a protective layer 130b. The semiconductor chips 10a and 10b may be manufactured by dicing the wafer 20 (see FIG. 1) along the partition due lines. Hereinafter, same descriptions of the semiconductor chips 10a and 10b shown in FIGS. 6 and 7 and the wafer 10 (see FIG. 4) will be omitted, and only differences therebetween will be described.

Referring to FIG. 6, the active layer 120a of the semiconductor chip 10a may include a first chamfer Ch1a, and the protective layer 130a may include a third chamfer Ch3a. A horizontal width of the active layer 120a and a horizontal width of the protective layer 130a may decrease away from the base substrate 110. In other words, a horizontal width of the first chamfer Ch1a and a horizontal width of the third chamfer Ch3a may decrease toward the base substrate 110. As shown, the horizontal width of the active layer 120a and the horizontal width of the protective layer 130a may uniformly decrease away from the base substrate 110. For example, a top side surface 120_Ca of the active layer 120a defining the first chamfer Ch1a and a top side surface 130_Ca of the protective layer 130a defining the third chamfer Ch3a may include flat surfaces having certain inclinations with reference to a top surface 120aU of the active layer 120a. That is, the horizontal width of the first chamfer Ch1a and the horizontal width of the third chamfer Ch3a may uniformly decrease toward the base substrate 110.

Referring to FIG. 7, the active layer 120b of the semiconductor chip 10b may include a first chamfer Ch1b, and the protective layer 130b may include a third chamfer Ch3b. A top side surface 120_Cb of the active layer 120b, which defines the first chamfer Ch1b, may have a stair-step shape. A top side surface 130_Cb of the protective layer 130b, which defines the third chamfer Ch3b, may also have a stair-step shape. For example, the active layer 120b and the protective layer 130b may have a stair-step shape in which a horizontal width thereof decreases away from the base substrate 110. In the processes of forming the first chamfer Ch1b and the third chamfer Ch3b, the first laser beam L1 may repeatedly move to and from the partition due line PDL (see FIG. 11A) of the wafer 20 (see FIG. 11A). By doing so, the first chamfer Ch1b and the third chamfer Ch3b may be formed in a stair-step shape.

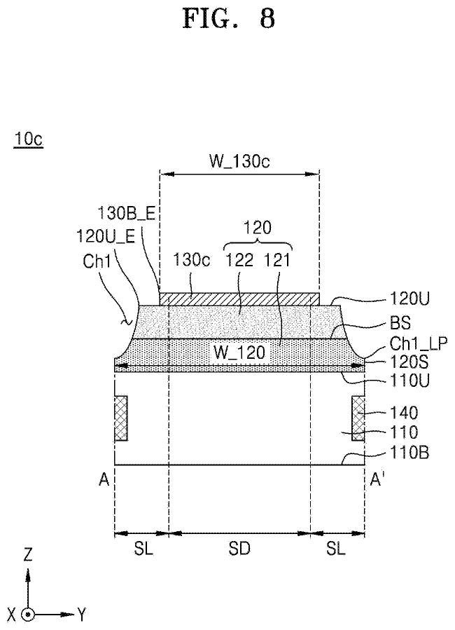

FIG. 8 is a cross-sectional view schematically illustrating a semiconductor chip 10c according to some embodiments, taken along the line A-A′ shown in FIG. 4. Referring to FIG. 8, the semiconductor chip 10c may include the base substrate 110, the active layer 120, the modifier 140, and a protective layer 130c. The semiconductor chip 10c may be manufactured by dicing the wafer 20 (see FIG. 1) along the partition due lines. Hereinafter, same descriptions of the semiconductor chip 10c shown in FIG. 8 and the wafer 10 in FIG. 4 will be omitted, and only differences therebetween will be described.

The protective layer 130c of the semiconductor chip 10c may be on the top surface 120U of the active layer 120. As a horizontal width W_130c of the protective layer 130c is less than a horizontal width W_120 of the active layer 120, the protective layer 130c may cover a portion of the active layer 120. That is, a horizontal area of the top surface of the protective layer 130c may be smaller than a horizontal area of the top surface 120U of the active layer 120.

As the protective layer 130c is not formed in a portion of the scribe lane region SL of the semiconductor chip 10c, a portion of the top surface 120U of the active layer 120 may be exposed to the outside. For example, an edge 130B_E of a bottom surface of the protective layer 130c may be apart from the edge 120U_E of the top surface 120U of the active layer 120 in a horizontal direction, and a top of the edge 120U_E of the top surface 120U of the active layer 120 may be exposed to the outside.

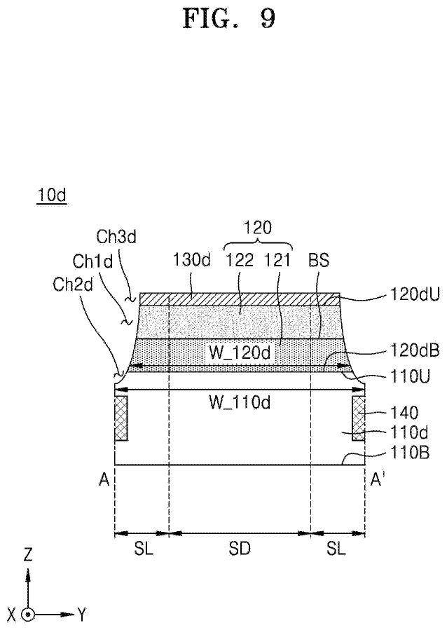

FIG. 9 is a cross-sectional view schematically illustrating a semiconductor chip 10d according to some embodiments, taken along the line A-A′ shown in FIG. 4. Referring to FIG. 9, the semiconductor chip 10d may include a base substrate 110d, an active layer 120d, the modifier 140, and a protective layer 130d. The semiconductor chip 10d may be manufactured by dicing the wafer 20 (see FIG. 1) along the partition due lines. Hereinafter, same descriptions of the semiconductor chip 10d (see FIG. 9) and the wafer 10 (see FIG. 4) will be omitted, and only differences therebetween will be described.

The active layer 120d of the semiconductor chip 10d may include a first chamfer Ch1d, the protective layer 130d may include a third chamfer Ch3d, and the base substrate 110d may include a second chamfer Ch2d. In processes of forming the first chamfer Ch1d, the protective layer 130d and the base substrate 110d may be partially removed, and the third chamfer Ch3d and the second chamfer Ch2d may be formed. Although FIG. 9 illustrates that the side surfaces of the first chamfer Ch1d, the second chamfer Ch2d, and the third chamfer Ch3d are curved surfaces, the side surfaces are not limited thereto and may have a flat shape or a stair-step shape.

The third chamfer Ch3d may completely penetrate from a top surface of the protective layer 130d to a bottom surface of the protective layer 130d and communicate with the first chamfer Ch1d. The first chamfer Ch1d may completely penetrate from the top surface 120dU of the active layer 120d to the bottom surface 120 dB of the active layer 120d and communicate the second chamfer Ch2d. Finally, the second chamfer Ch2d may extend from the top surface 110dU of the base substrate 110d to an inner portion of the base substrate 110d. For example, the first chamfer Ch1d, the second chamfer Ch2d, and the third chamfer Ch3d may be a trench having a continuous sidewall.

In some embodiments, the horizontal width W_120d of the active layer 120d may decrease toward the base substrate 110d. For example, the horizontal width W_120d of the active layer 120d on the top surface 120dU of the active layer 120d may be smaller about 15 μm to about 30 μm than the horizontal width W_110d of the bottom surface 110 dB of the base substrate 110d. The horizontal width W_120d of the active layer 120d of the bottom surface 120 dB of the active layer 120d may be smaller about 0.5 μm to about 15 μm than the horizontal width W_110d of the bottom surface 110 dB of the base substrate 110d.

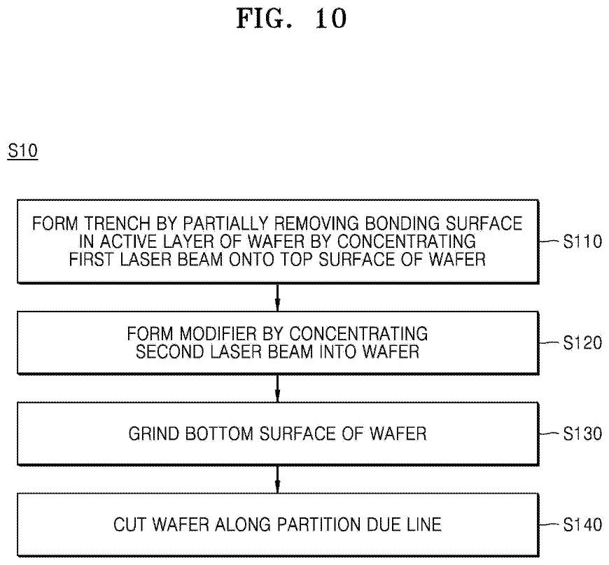

FIG. 10 is a flowchart schematically illustrating a method of dicing a wafer (S10) according to some embodiments. FIGS. 11A, 12A, 13A, 14A, and 15A are perspective views illustrating the method of dicing the wafer (S10) according to some embodiments, according to a process sequence. FIGS. 11B, 12B, 13B, 14B, 15B, and 12C are cross-sectional views illustrating the method of dicing the wafer (S10) according to some embodiments, according to a process sequence. Here, FIGS. 11B, 12B, 13B, 14B, 15B, and 12C are cross-sectional views illustrating a portion of the wafer 20 in corresponding drawings among FIGS. 11A, 12A, 13A, 14A, and 15A. Although a particular process of the method of dicing the wafer (S10) is described later than other processes, unless the particular process is described as being performed after the other processes, the particular process may be performed before the other processes.

Referring to FIG. 10, the method of dicing the wafer (S10) may include concentrating a first laser beam onto a top surface of a wafer and forming a trench for removing a portion of a bonding surface in an active layer of the wafer (S110), forming a modifier by concentrating a second laser beam into the wafer (S120), grinding a bottom surface of the wafer (S130), and cutting the wafer along partition due lines (S140).

Hereinafter, the method of dicing the wafer (S10) will be described in detail with reference to FIGS. 11A to 15B.

Referring to FIGS. 11A and 11B, the wafer 20 is mounted on a chuck table 40 such that a top surface 20U of the wafer 20 faces upward. That is, the wafer 20 may be mounted on the chuck table 40 such that the top surface 230U of the protective layer 230 faces upward. As shown, the wafer 20 may include the base substrate 210, the active layer 220, and the protective layer 230. In some embodiments, the active layer 220 may be formed on the base substrate 210, and the protective layer 230 may be formed on the active layer 220. In some embodiments, the active layer 220 may include a top active layer and a bottom active layer 221 bonded to each other with reference to the bonding surface BS.

In some embodiments, the protective layer 230 may be apart from the base substrate 210 with the active layer 220 therebetween. That is, the protective layer 230 may be not in direct contact with the base substrate 210. In some embodiments, the protective layer 230 is not formed in a portion of the scribe lane region SL, and therefore, a portion of the active layer 220 in the scribe lane region SL may be exposed to the outside. The wafer 20 may include a plurality of device-forming regions SD, in each of which a plurality of integrated devices are formed, and a scribe lane region SL defining the plurality of device-forming regions SD. The partition due line PDL may be in the scribe lane region SL. The wafer 20 may be partitioned into the plurality of semiconductor chips 10 along the partition due lines PDL. In some embodiments, the chuck table 40 may include an electrostatic chuck fixing the wafer 20 using an electrostatic force or a vacuum chuck fixing the wafer 20 using vacuum. Alternatively, the wafer 20 may be fixed onto the chuck table 40 through an adhesive tape.

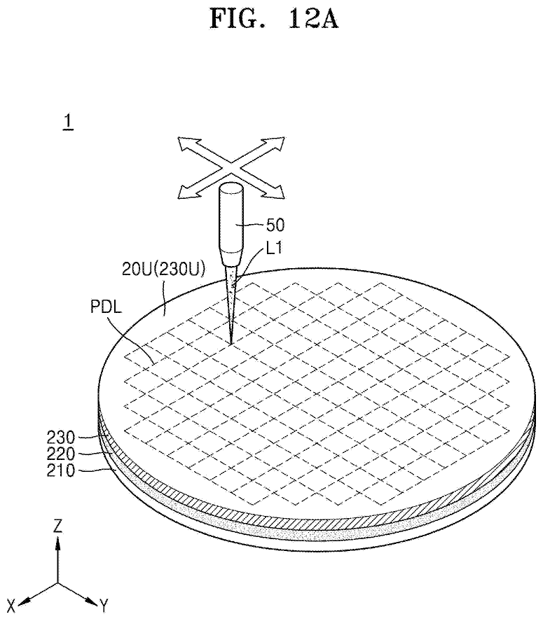

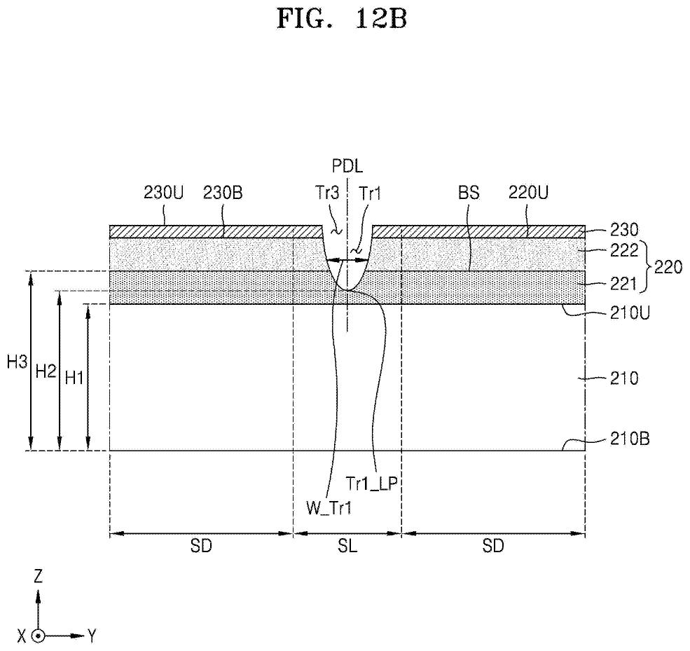

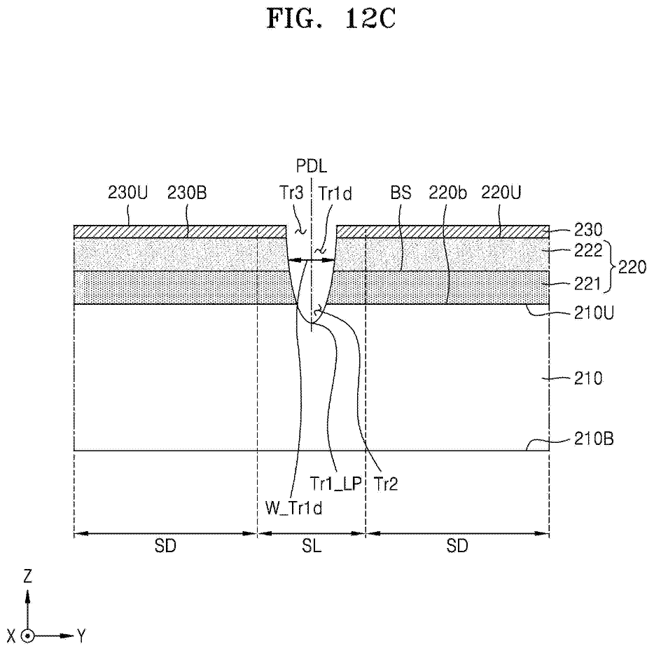

Referring next to FIGS. 12A and 12B, the first trench Tr1 and the third trench Tr3 are formed in each of the active layer 220 and the protective layer 230 by concentrating the first laser beam L1 onto the top surface 20U of the wafer 20. The first trench Tr1 and the third trench Tr3 may indicate a same trench. After a concentrator 50 has been arranged on an upper portion of the top surface 20U of the wafer 20, the concentrator 50 may concentrate the first laser beam L1 onto the top surfaces of the wafer 20, including the protective layer 230 and underlying active layer 220. A concentration point of the first laser beam L1 of the concentrator 50 may be aligned with the partition due line PDL. Thereafter, the concentrator 50 may move in the horizontal direction (the X direction or the Y direction) along the partition due line PDL, and may completely remove the protective layer 230 within the partition due line PDL and partially remove the active layer 220.

Accordingly, in the bonding surface BS of the active layer 220, the bonding surface BS on the partition due line PDL may be removed by the first laser beam L1. Regions from which the active layer 220 and the protective layer 230 have been removed may be defined as the first trench Tr1 and the third trench Tr3. The first trench Tr1 may extend inside from the top surface of the active layer 220, and the third trench Tr3 may completely penetrate from the top surface of the protective layer 230 to the bottom surface of the protective layer 230. The third trench Tr3 may communicate with the first trench Tr1. In some embodiments, the horizontal width W_Trl may decrease toward the base substrate 210.

In some embodiments, the horizontal width W_Tr1 of the first trench Tr1 may be from about 15 μm to about 30 μm on the top surface 220U of the active layer 220. In some embodiments, the lowermost portion Tr1_LP of the first trench TR1 may be in the bottom active layer 221. For example, a vertical level H2 of the lowermost portion Tr1_LP of the first trench TR1 may be lower than the vertical level H3 of the bonding surface BS and higher than the vertical level H1 of the top surface 210U of the base substrate 210.

Referring to FIG. 12C, the first laser beam L1 may completely remove the protective layer 230 and the active layer 220 within the partition due line PDL and remove a portion of base substrate 210. Regions from which the active layer 220 and the protective layer 230 have been removed may each be defined as a first trench Tr1d and the third trench Tr3, and a region from which the base substrate 210 has been removed may be defined as a second trench Tr2. The first trench Tr1d may communicate with the third trench Tr3, and the second trench Tr2 may communicate with the first trench Tr1d. That is, the first trench Tr1d, the second trench Tr2, and the third trench Tr3 may be a single continuous trench.

The first trench Tr1d may completely penetrate from the top surface 220U of the active layer 220 to the bottom surface 220B of the active layer 220, and the lowermost portion Tr2_LP of the second trench Tr2 may be in the base substrate 210. In some embodiments, the horizontal width W_Tr1d of the first trench Tr1d may be from about 15 μm to about 30 μm on the top surface 220U of the active layer 220 and may be from about 0.5 μm to about 15 μm on the bottom surface 220B of the active layer 220.

Referring again to FIG. 12B, the first laser beam L1 may have a wavelength absorbable by the protective layer 230 and the active layer 220. In some embodiments, a wavelength of the first laser beam L1 may be from about 300 nm to about 800 nm. In some embodiments, a pulse width of the first laser beam L1 may be from about 20 ns to about 80 ns. In some embodiments, an output of the first laser beam L1 may be from about 1 W to about 5 W.

In some embodiments, in a process of removing the protective layer 230 and the active layer 220, the concentrator 50 may move to and from the partition due line PDL of the wafer 20 until the first trench Tr1 has a preset thickness. For example, the first laser beam L1 may be repeatedly concentrated onto the top surface 20U of the wafer 20 along the partition due line PDL until the vertical level H2 of the lowermost portion Tr1_LP of the first trench TR1 is lower than the vertical level H3 of the bonding surface BS.

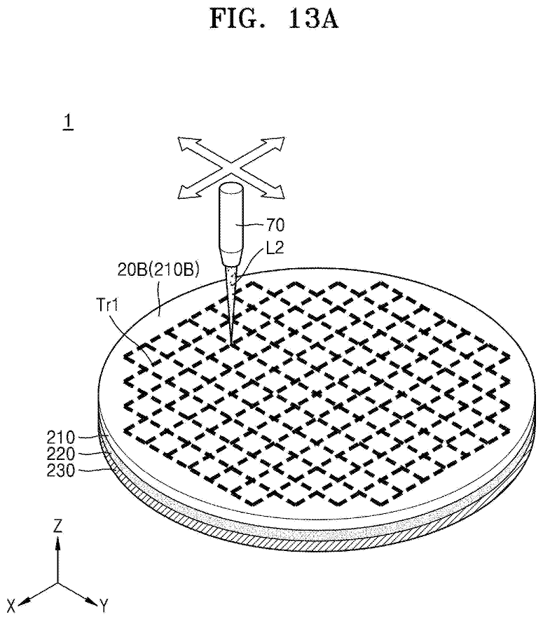

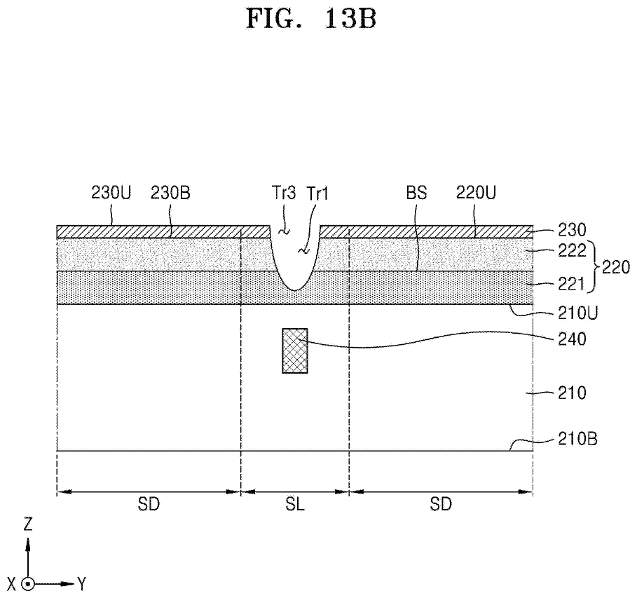

Referring to FIGS. 13A and 13B, the modifier 240 may be formed in the wafer 20 by concentrating the laser beam L2 into the wafer 20. By flipping the wafer 20 in which the first trench Tr1, the wafer 20 may be mounted on the chuck table 40 such that a bottom surface 20B of the wafer 20 faces upward. However, the embodiment is not limited thereto, and the wafer 20 may also be mounted on the chuck table 40 such that the top surface 20U of the wafer 20 faces upward.

A concentrator 70 configured to concentrate the second laser beam L2 may be aligned with the wafer 20 such that a concentration point of the second laser beam L2 and the first trench Tr1 are in one straight line in the vertical direction (the Z direction). In some embodiments, the wafer 20 and the concentrator 70 may be aligned by measuring a position of the first trench Tr1 through an imaging apparatus (not shown). The concentrator 70 aligned with the wafer 20 may move in the horizontal direction (the X direction or the Y direction) along the first trench Tr1.

The second laser beam L2 may have a wavelength having transmittance to the base substrate 210, and therefore, a concentration point may be in the base substrate 210. The second laser beam L2 may be concentrated along the first trench Tr1 through the concentrator 70, and the modifier 240 apart from the first trench Tr1 in the vertical direction may be formed in the base substrate 210. As the modifier 240 is formed in the base substrate 210, cracks may be formed in the base substrate 210 near the modifier 240. In some embodiments, a wavelength of the second laser beam L2 may be from about 800 nm to about 1200 nm. In some embodiments, an output of the second laser beam L2 may be from about 1 W to about 3 W. In some embodiments, a pulse width of the second laser beam L2 may be from about 20 ns to about 80 ns.

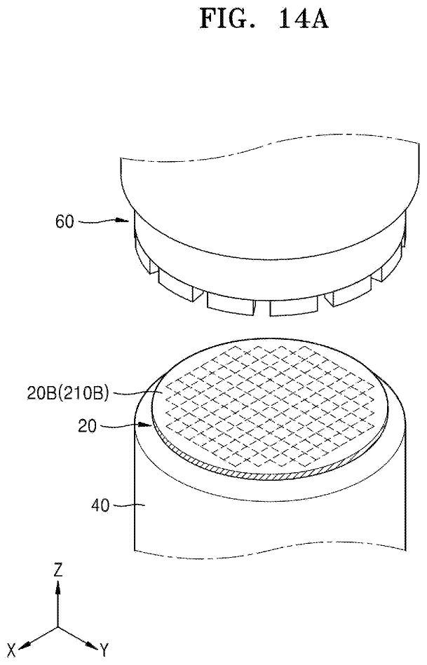

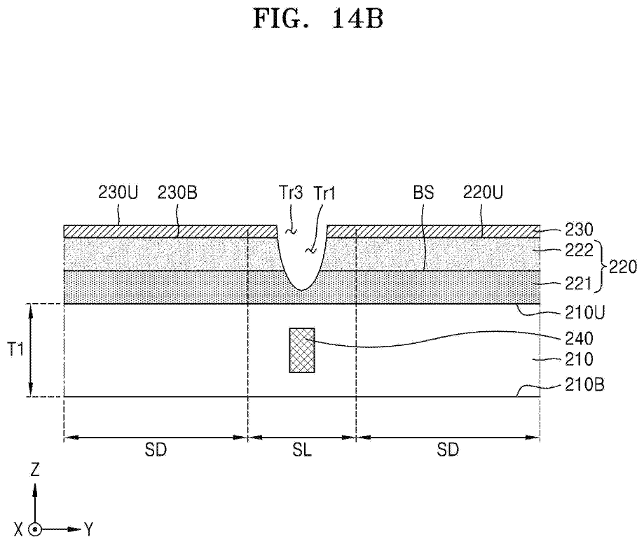

Referring to FIGS. 14A and 14B, a bottom of the base substrate 210 is removed by grinding the bottom surface 20B of the wafer 20. A grinding process to form the base substrate 210 in a preset thickness is performed. A grinding device 60 may be arranged on the bottom surface of the wafer 20, a chuck table and/or the grinding device 60 supporting the wafer 20 may be rotated to bring the bottom surface 20B of the wafer 20 in contact with the grinding device 60 and perform grinding, and by doing so, the base substrate 210 may be formed in a preset thickness. For example, through the grinding process, the thickness T1 of the base substrate 210 may be formed in about 100 μm. In some embodiments, a portion of the modifier 240 may be removed through the grinding process. In some embodiments, the grinding process may include chemical mechanical polishing (CMP) process.

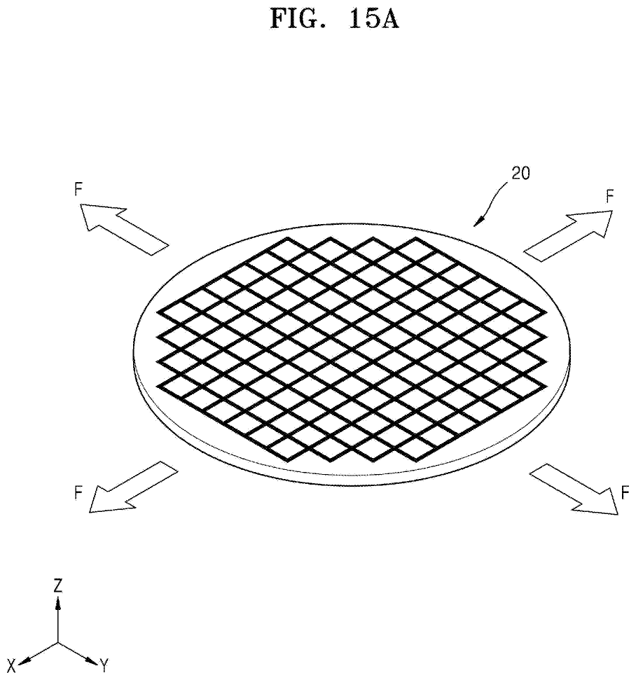

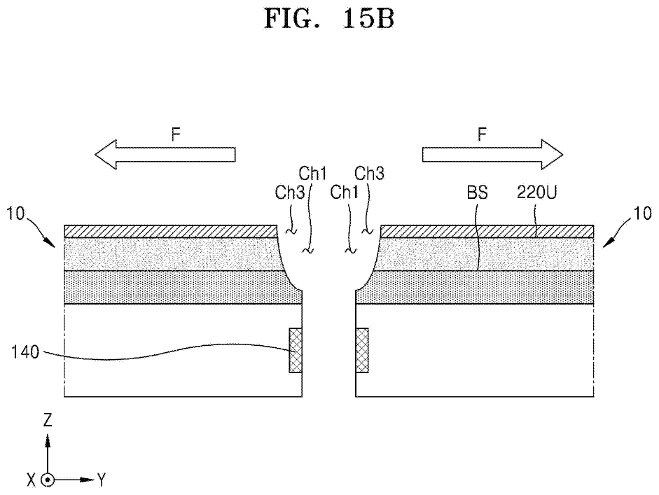

Referring to FIGS. 15A and 15B together with FIG. 14B, the wafer 20 is partitioned along the partition due line PDL. That is, a plurality of semiconductor chips may be formed by partitioning the wafer 20 with reference to the first trench Tr1 and the modifier 240. By applying an external force to the wafer 20, cracks from the modifier 240 of the base substrate 210 toward the first trench Tr1 may be formed, and the wafer 20 may be broken along the modifier 240. In some embodiments, the wafer 20 may be attached to a dicing tape (not shown), and an external force may be applied to the wafer 20 while expanding the dicing tape.

Compared with other regions, the modifier 240 of the wafer 20 may be more easily damaged due to the external force. As the dicing tape expands, cracks may occur in the modifier 240 due to the external force applied to the wafer 20. The cracks may extend upward and downward from the modifier 240 and may be in contact with the bottom surface 210B of the base substrate 210 and the first trench Tr1. Accordingly, the wafer 20 may be broken and divided into the plurality of semiconductor chips 10. As the wafer 20 is broken, the first trench Tr1 and the third trench Tr3 may be the first chamfer Ch1 and the third chamfer Ch3 of each of the plurality of semiconductor chips 10.

As the first trench Tr1 extends downward from the top surface 220U of the active layer 220 in the vertical direction (the Z direction) of the bonding surface BS of the active layer 220, the crack started from the modifier 240 may not extend to the bonding surface BS of the active layer 220. That is, the crack starting from the modifier 240 toward the first trench Tr1 may be in contact with the first trench Tr1 under the bonding surface BS of the active layer 220. Accordingly, damages to a vicinity of the bonding surface BS of the active layer 220 in the process of dividing the wafer 20 may be inhibited.

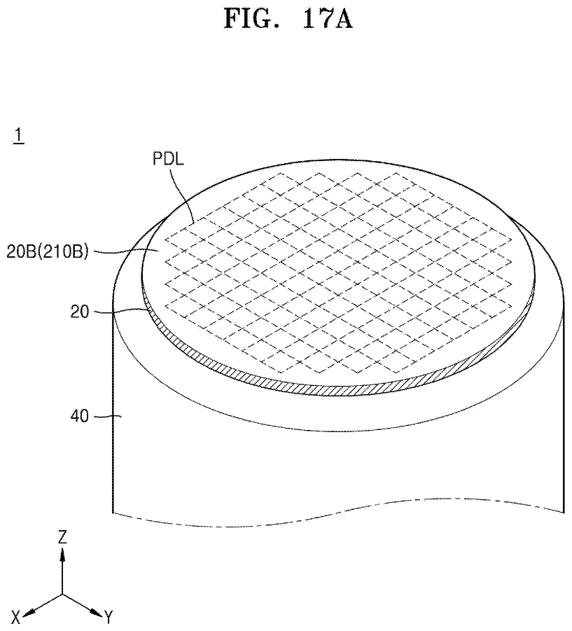

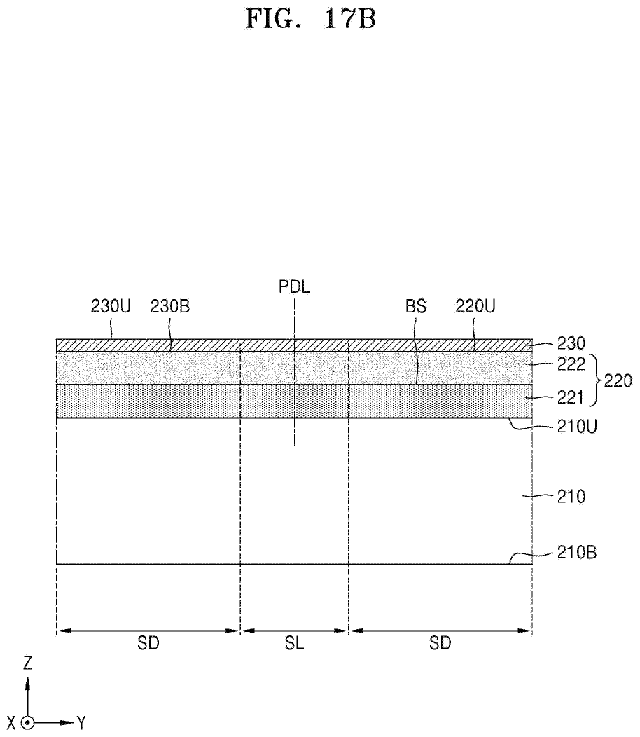

FIG. 16 is a flowchart schematically illustrating a method of dicing the wafer (S20) according to some embodiments; and FIGS. 17A, 18A, 19A, 20A, and 21A are perspective views illustrating the method of dicing the wafer (S20) according to some embodiments, according to a process sequence. FIGS. 17B, 18B, 19B, 20B, and 21B are cross-sectional views illustrating the method of dicing the wafer (S20) according to some embodiments, according to a process sequence. Here, FIGS. 17B, 18B, 19B, 20B, and 21B are cross-sectional views illustrating a portion of the wafer 20 in corresponding drawings among FIGS. 17A, 18A, 19A, 20A, and 21A.

Referring to FIG. 16, the method of dicing the wafer (S20) may include grinding the bottom surface of the wafer (S210), forming the modifier by concentrating the second laser beam into the wafer (S220), aligning the modifier with a concentration point of the first laser beam (S230), forming a trench for removing a portion of the bonding surface in the active layer of the wafer by concentrating the first laser beam on the top surface of the wafer (S240), and cutting the wafer along the partition due line (S250).

Although the grinding of the bottom surface of the wafer (S210) is described prior to other processes, sequences of the method of dicing the wafer (S20) is not limited thereto, and the grinding of the bottom surface of the wafer (S210) may be performed after the other processes. In some embodiments, the grinding of the bottom surface of the wafer (S210) may be performed after the forming of the modifier (S220). That is, the grinding of the bottom surface of the wafer (S210) may be performed between the forming of the modifier (S220) and the aligning of the first laser beam (S230).

Hereinafter, the method of dicing the wafer (S20) will be described in detail with reference to FIGS. 17A to 21B. However, same descriptions of the method of dicing the wafer (S20) shown in FIGS. 17A to 21B and the method of dicing the wafer (S20) shown in FIGS. 11A to 15B will be omitted, and only differences therebetween will be described.

Referring to FIGS. 17A and 17B, the wafer 20 is mounted on the chuck table 40 such that the bottom surface 20B of the wafer 20 faces upward. That is, the wafer 20 may be mounted on the chuck table 40 such that the bottom surface 210B of the base substrate 210 faces upward. The wafer 20 may include the base substrate 210, the active layer 220, and the protective layer 230. In some embodiments, the active layer 220 may be formed on the base substrate 210, and the protective layer 230 may be formed on the active layer 220. In some embodiments, the active layer 220 may include a top active layer and a bottom active layer 220 bonded to each other with reference to the bonding surface BS.

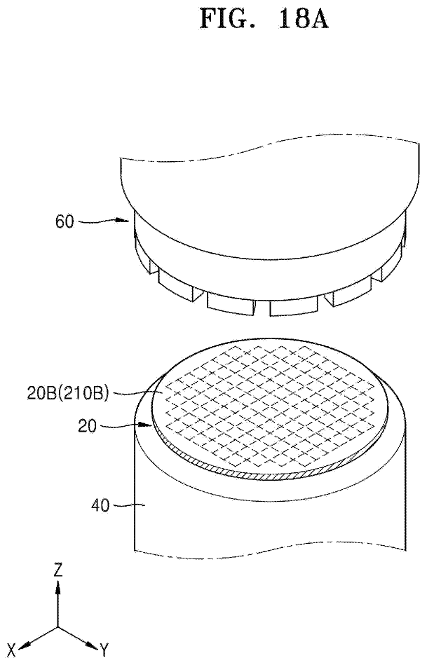

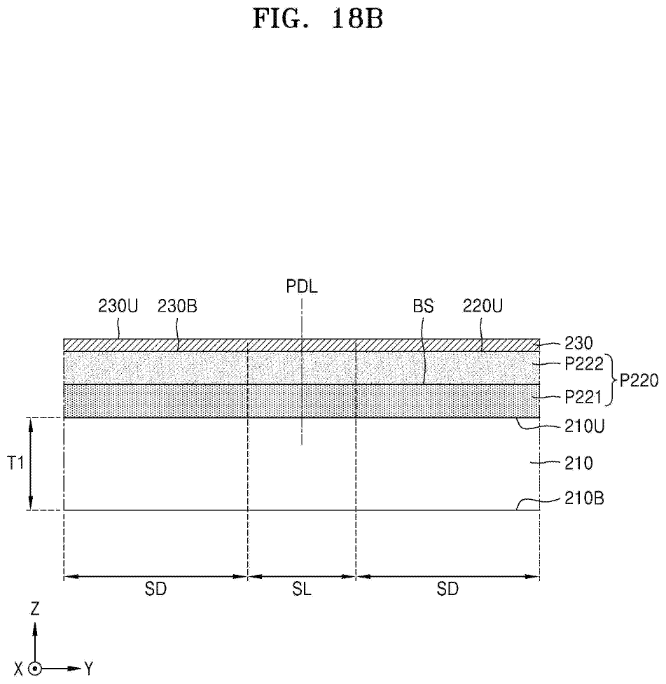

Referring to FIGS. 18A and 18B, the lower portion of the base substrate 210 is removed by grinding the bottom surface 20B of the wafer. A grinding process to form the base substrate 210 in a preset thickness is performed. The grinding device 60 may be arranged on the bottom surface of the wafer 20, a chuck table and/or the grinding device 60 supporting the wafer 20 may be rotated to bring the bottom surface 20B of the wafer 20 in contact with the grinding device 60 and perform grinding, and by doing so, the base substrate 210 may be formed in a preset thickness. In some embodiments, the grinding process may include CMP process.

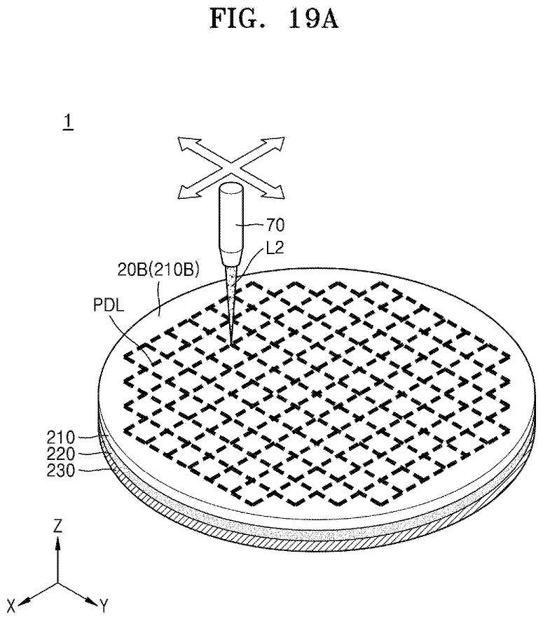

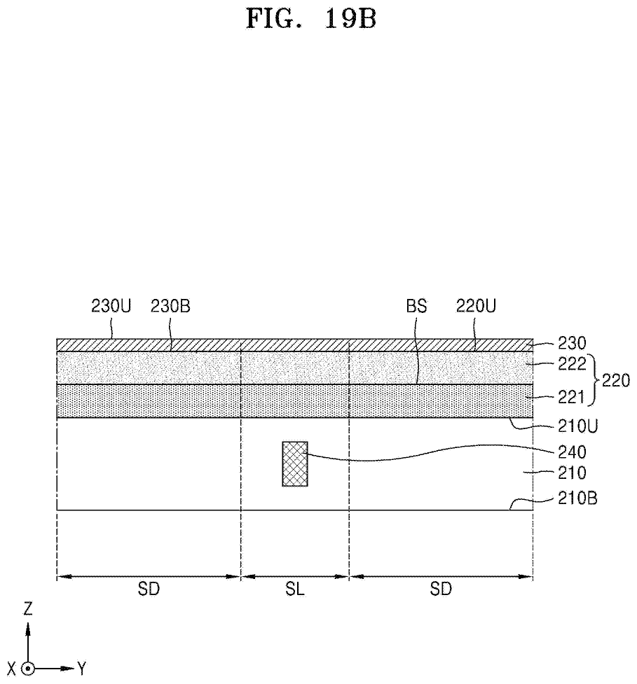

Referring to FIGS. 19A and 19B, the modifier 240 may be formed in the wafer 20 by concentrating the second laser beam L2 into the wafer 20. After the concentrator 70 has been arranged on an upper portion of the bottom surface 20B of the wafer 20, the concentrator 70 may concentrate the second laser beam L2 into the base substrate 210. The concentrator 70 and the wafer 20 may be aligned such that the concentration point of the second laser beam L2 is in one straight line with the partition due line PDL in the vertical direction. Next, the concentrator 50 may form the modifier 240 in the base substrate 210 while moving in the horizontal direction (the X direction or the Y direction) along the partition due line PDL.

The second laser beam L2 may have a wavelength having transmittance to the base substrate 210, and therefore, the concentration point may be in the base substrate 210. The modifier 240 may be formed in the base substrate 210 by concentrating the second laser beam L2 along the partition due line PDL through the concentrator 70. As the modifier 240 is formed in the base substrate 210, cracks may be formed in the base substrate 210 near the modifier 240.

In some embodiments, a wavelength of the second laser beam L2 may be from about 800 nm to about 1200 nm. In some embodiments, an output of the second laser beam L2 may be from about 1 W to about 3 W. In some embodiments, a pulse width of the second laser beam L2 may be from about 20 ns to about 80 ns.

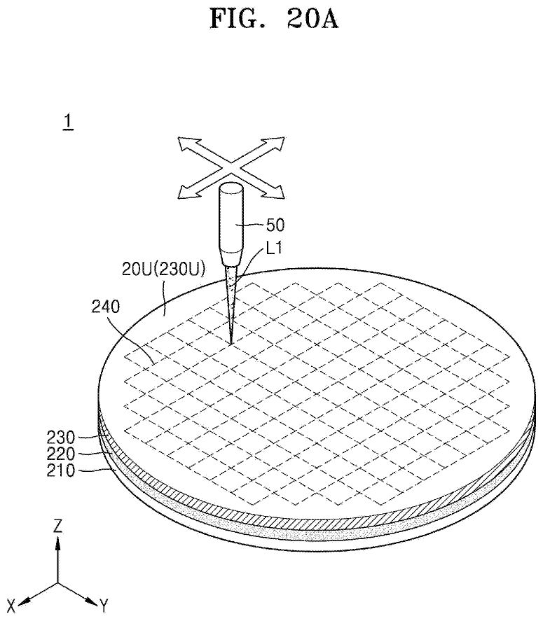

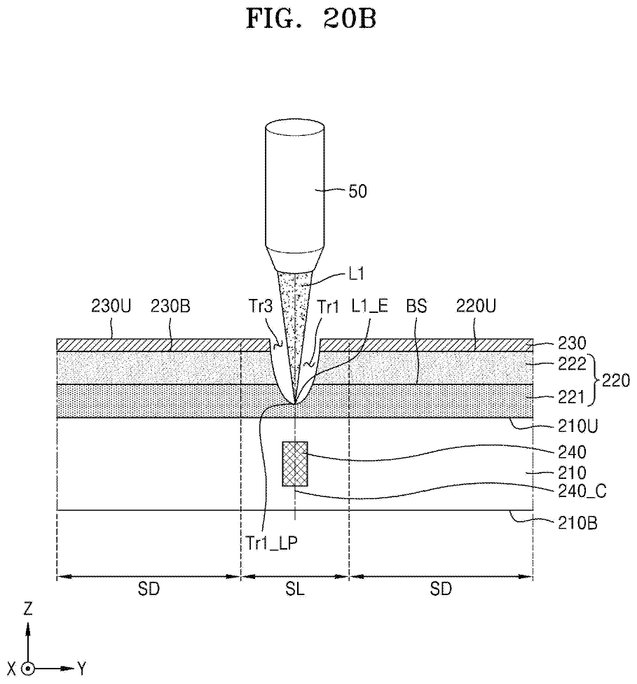

Referring to FIGS. 20A and 20B, the first trench Tr1 and the third trench Tr3 are formed in each of the active layer 220 and the protective layer 230 by concentrating the first laser beam L1 onto the top surface 20U of the wafer 20. In addition, by flipping the wafer 20 in which the first trench Tr1 is formed, the wafer 20 may be mounted on the chuck table 40 such that the top surface 20U of the wafer 20 faces upward. The concentrator 50 and the wafer 20 may be aligned with each other. More particularly, the concentrator 50 and the wafer 20 may be aligned with each other such that a concentration point L1_E of the first laser beam L1 of the concentrator 50 and a center 240_C of the modifier 240 of the wafer 20 are in one straight line in the vertical direction (the Z direction). In some embodiments, a position of the modifier 240 may be measured through an imaging apparatus (not shown), and the wafer 20 and the concentrator 50 may be aligned to each other such that the center 240_C of the modifier 240 and the concentration point L1_E of the first laser beam L1 are aligned in a row.

The concentrator 50 aligned with the wafer 20 may move in the horizontal direction (the X direction or the Y direction) along the modifier 240. Accordingly, in the bonding surface BS of the active layer 220, the bonding surface BS on the modifier 240 may be removed by the first laser beam L1. For example, in the process of forming the first trench Tr1, the lowermost portion Tr1_LP of the first trench TR1 may be in the concentration point L1_E of the first laser beam L1, and the lowermost portion Tr1_LP of the first trench TR1 may be on a same straight line with the modifier 240 in the vertical direction (the Z direction). Advantageously, as the first laser beam L1 has the concentration point L1_E on the surface of the protective layer 230 or the active layer 220, the accuracy of concentrating of the first laser beam L1 may be higher than the accuracy of concentrating of the second laser beam L1. Therefore, after the forming of the modifier 240, the first trench Tr1 may be formed along the modifier 240, and thus, misaligning of the modifier 240 and the lowermost portion Tr1_LP of the first trench TR1 may be reduced/inhibited.

In some embodiments, the first laser beam L1 may have a wavelength having absorbance to the protective layer 230 and the active layer 220. In some embodiments, a wavelength of the first laser beam L1 may be from about 300 nm to about 800 nm. The pulse width of the first laser beam L1 may be from about 20 ns to about 80 ns. The output of the first laser beam L1 may be from about 1 W to about 5 W.

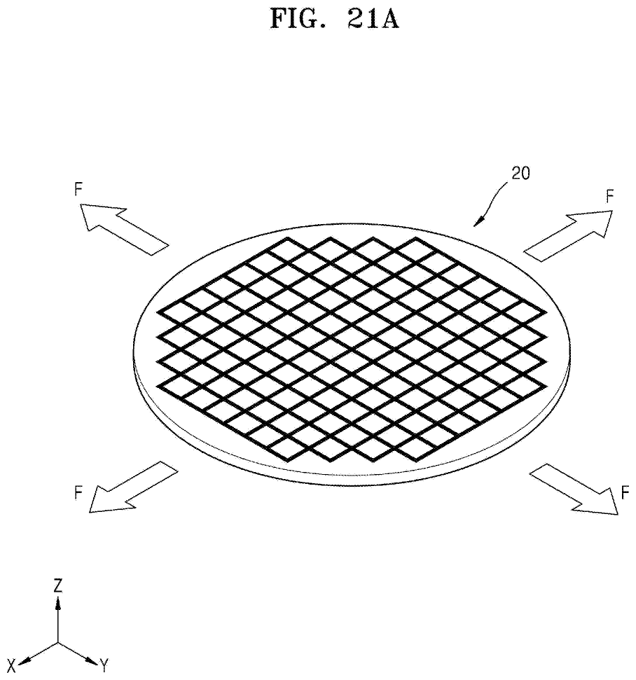

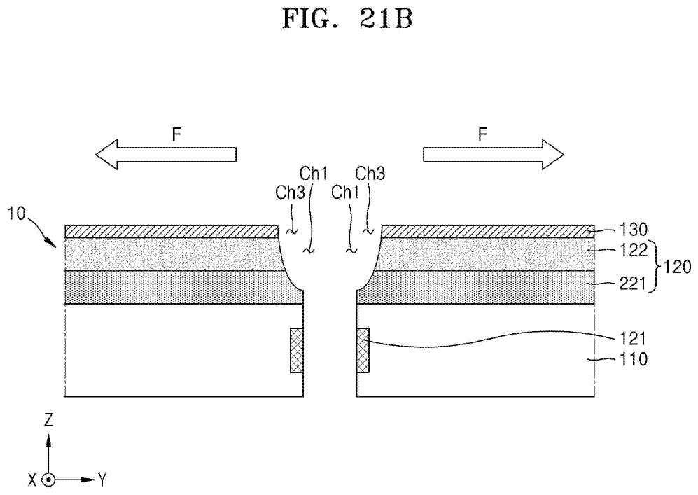

Referring to FIGS. 21A and 21B together with FIG. 20B, the wafer 20 is partitioned along the partition due line PDL. That is, a plurality of semiconductor chips may be formed by partitioning the wafer 20 with reference to the first trench Tr1 and the modifier 240. By applying an external force to the wafer 20, cracks from the modifier 240 of the base substrate 210 toward the first trench Tr1 may be formed, and the wafer 20 may be broken along the modifier 240. In some embodiments, the wafer 20 may be attached to a dicing tape (not shown), and an external force may be applied to the wafer 20 while expanding the dicing tape. Compared with other regions, the modifier 240 of the wafer 20 may be more easily damaged due to the external force. As the wafer 20 is broken, the first trench Tr1 and the third trench Tr3 may be the first chamfer Ch1 and the third chamfer Ch3 of each of the plurality of semiconductor chips 10.

The crack started due to the external force may extend from the modifier 240 toward the first trench Tr1 and be in contact with the first trench Tr1 under the bonding surface BS of the active layer 220. Accordingly, damages to a vicinity of the bonding surface BS of the active layer 220 in the process of dividing the wafer 20 may be inhibited.

While the inventive concept has been particularly shown and described with reference to embodiments thereof, it will be understood that various changes in form and details may be made therein without departing from the spirit and scope of the following claims.

1. A semiconductor chip, comprising:
an active layer on a top surface of an underlying base substrate, said active layer having: bonding surface therein that delineates an interface between a bottom active layer and a top active layer extending on the bottom active layer, and a chamfered edge that extends entirely through the top active layer to fully expose a sidewall thereof but only partially through the bottom active layer, such that the chamfered edge has a vertical height greater than a thickness of the top active layer but less than a combined thickness of the top and bottom active layers; and
a protective layer covering at least a portion of a top surface of the active layer, which extends between the protective layer and the base substrate.

2. The semiconductor chip of claim 1, wherein a vertical level of a bottom of the chamfered edge is higher than a vertical level of the top surface of the base substrate.

3. The semiconductor chip of claim 2,
wherein, in a region where the chamfered edge is not formed, a horizontal width of the active layer is equivalent to a horizontal width of the base substrate; and
wherein, in a region where the chamfered edge is formed, a horizontal width of the active layer decreases in a direction away from the top surface of the base substrate.

4. The semiconductor chip of claim 2,
wherein a horizontal width of the top surface of the active layer is about 15 μm to about 30 μm smaller than a horizontal width of a bottom surface of the base substrate.

5. The semiconductor chip of claim 1, wherein the base substrate further comprises a modifier formed along a side surface of the base substrate; and wherein the modifier is spaced apart from a bottom of the chamfered edge in a vertical direction.

6. The semiconductor chip of claim 1, wherein the top active layer and the bottom active layer are bonded to each other along the bonding surface by hybrid bonding.

7. A semiconductor chip, comprising:
a base substrate;
an active layer formed on a top surface of the base substrate;
a protective layer covering at least a portion of a top surface of the active layer and being apart from the base substrate in a vertical direction with the active layer therebetween; and
a first chamfer extending inside from the top surface of the active layer and formed along an edge of the top surface of the active layer;
wherein the active layer includes a top active layer and a bottom active layer distinguished from each other with reference to a bonding surface extending between the top active layer and the bottom active layer; and
wherein a vertical level of a bottom of the first chamfer is lower than a vertical level of the bonding surface in the active layer.

8. The semiconductor chip of claim 7,
wherein the vertical level of the bottom of the first chamfer is higher than a vertical level of the top surface of the base substrate.

9. The semiconductor chip of claim 8,
wherein, in a region in which the first chamfer is not formed, a horizontal width of the active layer is equivalent to a horizontal width of the base substrate; and
wherein, in a region in which the first chamfer is formed, a horizontal width of the active layer decreases away from the base substrate.

10. The semiconductor chip of claim 8,
wherein a side surface of the active layer comprises a top side surface, which define the first chamfer, and a bottom side surface; and
wherein the top side surface of the active layer extends from an edge of the top surface of the active layer to an edge of the bottom side surface of the active layer.

11. The semiconductor chip of claim 7,
wherein the base substrate comprises a second chamfer extending inside from a top surface;
wherein the first chamfer completely passes through the active layer; and
wherein the second chamfer communicates with the first chamfer.

12. The semiconductor chip of claim 11,
wherein a horizontal width of a top surface of the active layer is about 15 μm to about 30 μm smaller than a horizontal width of a bottom surface of the base substrate; and
wherein a horizontal width of a bottom surface of the active layer is about 0.5 μm to about 15 μm smaller than the horizontal width of the bottom surface of the base substrate.

13.-18. (canceled)

19. A method of dicing a wafer, comprising:
forming a trench along a partition due line of a wafer by concentrating a first laser beam onto a surface of the wafer and removing a portion of a protective layer and a portion of an active layer, wherein the wafer comprises a base substrate, the active layer formed on a surface of the base substrate and having a bonding surface therein, and the protective layer covering the active layer; and
positioning, in the base substrate, a concentration point of a second laser beam having a wavelength transmitted through the wafer, and forming a modifier in the base substrate along the partition due line; and
wherein during the forming of the trench, a portion on the partition due line is removed from the bonding surface of the active layer.

20. The method of claim 19, wherein, in the forming of the trench, a horizontal width of the trench decreases toward the base substrate.

21. The method of claim 19, wherein, in the forming of the trench, the first laser beam is repeatedly concentrated onto a top surface of the wafer along the partition due line until the trench has a preset thickness.

22. The method of claim 19, wherein, in the forming of the trench, a portion of the base substrate is removed along the partition due line.

23. The method of claim 19, wherein, in the forming of the trench, the first laser beam has an output from about 1 W to about 5 W.

24. The method of claim 19, wherein the forming of the trench is performed after the forming of the modifier.

25. The method of claim 24, further comprising aligning the modifier with a concentration point of the first laser beam, before the forming of the trench.

26. The method of claim 19,
wherein the protective layer is apart from the base substrate with the active layer therebetween;
wherein the active layer is divided into a top active layer and a bottom active layer with reference to the bonding surface; and
wherein the top active layer is bonded to the bottom active layer in the bonding surface through hybrid bonding.

27.-37. (canceled)
